(19) United States
(12) Patent Application Publication
(10) Pub. No.: US 2026/0180571 A1
(43) Pub. Date: Jun. 25, 2026

(54) PARALLEL CIRCUIT ARCHITECTURE FOR MULTI-PHASE POWER STAGE CHIPS, CIRCUIT BOARD, AND ELECTRONIC DEVICE

(71) Applicant: Innovision Semiconductor Inc., Dongguan (CN)

(72) Inventors: Jiaxiong ZHOU, Dongguan (CN); Haipeng ZHU, Dongguan (CN); Yujie LIN, Dongguan (CN); Huijia ZHUO, Dongguan (CN); Xuening LI, Dongguan (CN)

(73) Assignee: Innovision Semiconductor Inc., Dongguan, Guangdong (CN)

(21) Appl. No.: 19/191,372

(22) Filed: Apr. 28, 2025

(30) Foreign Application Priority Data
Dec. 20, 2024 (CN) 202411886595.5

(51) Int. Cl. H03K 17/16; H03K 17/00

(52) U.S. Cl. CPC H03K 17/165; H03K 17/002; H03K 2217/0027

(57) ABSTRACT

Disclosed are a parallel circuit architecture for multi-phase power stage chips, a circuit board, and an electronic device, which relate to the technical field of electronic circuits. When it is detected that the current at a target current detection terminal is greater than the currents at the remaining current detection terminals, a duty cycle of a target pulse signal is reduced to equalize the current across each power stage chip. When it is detected that the current at the target current detection terminal is less than the currents at the remaining current detection terminals, it indicates that the duty cycle of the target pulse signal is excessively low, and therefore the duty cycle of the target pulse signal is increased to equalize the current across each power stage chip.

### CROSS-REFERENCE TO RELATED APPLICATION

This application claims priority to Chinese patent application No. 202411886595.5, filed Dec. 20, 2024. The content of this application is incorporated herein by reference in their entirety.

### TECHNICAL FIELD

The present disclosure relates to the technical field of electronic circuits, and in particular, to a parallel circuit architecture for multi-phase power stage chips, a circuit board, and an electronic device.

### BACKGROUND

A power stage chip is a chip with temperature detection, current detection, current balancing and driving functions. Power stage chips are commonly configured to supply power to GPUs and CPUs, and are widely used in servers and artificial intelligence (AI) applications.

In related technologies, power stage chips are responsible for voltage conversion and output. Multiple power stage chips in parallel have the characteristics of high conversion efficiency, high integration density, high-current capability, and high-frequency operation. In applications that require high power and high efficiency, such as industrial motor drives, electric vehicles, charging piles, and uninterruptible power supply (UPS), it is necessary to use multiple power stage chips in parallel. To ensure a consistent drain current among the parallel power stage chips during both on-state and switching transients, and to avoid the problem of static and dynamic current imbalance due to uneven current distribution, it is necessary to equalize the output current across each power stage chip.

However, in the existing parallel circuit architectures for multi-phase power stage chips, when multiple power stage chips are connected in parallel, the output currents of the respective power stage chips are different from each other, resulting in reduced circuit stability and service life.

### SUMMARY

The present disclosure aims to solve at least one of the technical problems existing in the existing technologies. To this end, a parallel circuit architecture for multi-phase power stage chips, a circuit board and an electronic device are proposed, which can equalize the currents across power stage chips connected in parallel, thereby ensuring circuit stability and improving service life.

According to an embodiment of a first aspect of the present disclosure, a parallel circuit architecture for a plurality of multi-phase power stage chips may include:
a master controller module including a plurality of current detection terminals and a plurality of pulse output terminals, where the number of the current detection terminals is in one-to-one correspondence with the number of the pulse output terminals; and
a plurality of current modules, where the current detection terminals are in one-to-one correspondence with the current modules; each of the current modules includes a plurality of power stage chips, and the number of the pulse output terminals is equal to the number of power stage chips in one current module; and a control terminal of each power stage chip in the current module is connected to the pulse output terminal in one-to-one correspondence.

The current detection terminals are each connected to a current detection pin of one of the power stage chips in a corresponding current module, the power stage chips in the respective current modules, which are connected to the current detection terminals, are connected to different pulse output terminals.

The master controller module is configured to:
output pulse signals through the respective pulse output terminals, and detect currents of corresponding power stage chips through the current detection terminals connected thereto;
when it is detected that the current at a target current detection terminal is greater than the current at the remaining current detection terminals, reduce a duty cycle of a pulse signal at the pulse output terminal connected to the power stage chip connected to the target current detection terminal; and
when it is detected that the current at the target current detection terminal is less than the current at the remaining current detection terminals, increase the duty cycle of the pulse signal at the pulse output terminal connected to the power stage chip connected to the target current detection terminal.

According to the first aspect of the present disclosure, the parallel circuit architecture for the plurality of multi-phase power stage chips has at least the following beneficial effects. In the circuit architecture of the embodiments of the present disclosure, the plurality of current modules are connected in parallel, and the power stage chips in each current module are connected in parallel. The pulse output terminal of the master controller module outputs a pulse signal. Because the control terminal of each power stage chip in the current module is connected to the pulse output terminal in one-to-one correspondence, each power stage chip in the current module is in one-to-one correspondence with the pulse signal. The current detection terminal is connected to a current detection pin of one of the power stage chips in a corresponding current module. The power stage chips in the respective current modules, which are connected to the current detection terminals, are connected to different pulse output terminals. A target current detection terminal is any one of the plurality of current detection terminals. When it is detected that the current at the target current detection terminal is greater than the currents at the remaining current detection terminals, it indicates that the output current of the power stage chip connected to the target current detection terminal is greater than the currents of the remaining power stage chips. The current is primarily related to the duty cycle of the pulse signal. That is, the duty cycle of the pulse signal connected to the power stage chip connected to the target current detection terminal is excessively high. A target pulse signal is the pulse signal received by the power stage chip connected to the target current detection terminal, and the current of each power stage chip connected to the target pulse signal is excessively high. Therefore, the duty cycle of the target pulse signal is reduced to equalize the current across each power stage chip. When it is detected that the current at the target current detection terminal is less than the currents at the remaining current detection terminals, it indicates that the duty cycle of the target pulse signal is excessively low, and accordingly, the duty cycle of the target pulse signal is increased to equalize the current across each power stage chip. In this way, the output currents of the power stage chips connected in parallel are equalized, thereby ensuring circuit stability and improving service life. In addition, in the present disclosure, a single pulse signal controls a plurality of power stage chips, saving pins of the master controller module.

According to some embodiments of the first aspect of the present disclosure, the master controller module includes a plurality of first signal processing subcircuits that are in one-to-one correspondence with the pulse output terminals.

The first signal processing subcircuit includes a first operational transconductance amplifier, a first resistor, a second resistor, a third resistor, a first current source, and a first signal processing unit. A positive input terminal of the first operational transconductance amplifier is grounded through the first resistor. Both the positive input terminal of the first operational transconductance amplifier and the first resistor serve as a first current input terminal of the first signal processing subcircuit. The first current input terminal is connected to a corresponding current detection terminal. An inverting input terminal of the first operational transconductance amplifier is grounded through the second resistor. Both the inverting input terminal of the first operational transconductance amplifier and the second resistor serve as a second current input terminal of the first signal processing subcircuit, and the second current input terminal is connected to the target current detection terminal. An output terminal of the first operational transconductance amplifier is grounded through the third resistor. An output terminal of the first current source and a voltage input terminal of the first signal processing unit are connected to a net between the third resistor and the output terminal of the first operational transconductance amplifier. An output terminal of the first signal processing unit serves as the pulse output terminal corresponding to the target current detection terminal, and a signal input terminal of the first signal processing unit is connected to a signal output terminal of the first signal processing unit.

The first signal processing unit is configured to increase or reduce the duty cycle of an output signal at the signal output terminal of the first signal processing unit based on a voltage across the third resistance.

According to some embodiments of the first aspect of the present disclosure, the first signal processing unit includes a first field effect transistor, a second field effect transistor, a third field effect transistor, a fourth field effect transistor, a fifth field effect transistor, and a fourth resistor. A gate of the first field effect transistor serves as a signal input terminal of the first signal processing unit. The gate of the first field effect transistor is connected to a gate of the second field effect transistor. A drain of the first field effect transistor is connected to a drain of the second field effect transistor, and a source of the second field effect transistor is grounded. One end of the fourth resistor is connected to a source of the first field effect transistor, and the other end of the fourth resistor serves as a voltage input terminal of the first signal processing unit. One end of the first capacitor is connected to the drain of the second field effect transistor, and the other end of the first capacitor is grounded. A gate of the third field effect transistor is connected to the gate of the second field effect transistor. A source of the third field effect transistor is grounded, and the source of the third field effect transistor is connected to the drain of the second field effect transistor. A gate of the fourth field effect transistor, and a gate of the fifth field effect transistor. A source of the fourth field effect transistor is grounded, and a drain of the fourth field effect transistor is connected to a drain of the fifth field effect transistor. A source of the fifth field effect transistor is connected to a supply voltage.

According to some embodiments of the first aspect of the present disclosure, the first signal processing unit further includes a first selector. A first input terminal of the first selector is connected to the drain of the fourth field effect transistor, and a second input terminal of the first selector is connected to the gate of the first field effect transistor. The first selector receives an external control signal, and an output terminal of the first selector serves as the signal output terminal of the first signal processing unit.

When the external control signal is at a low level, the signal at the output terminal of the first selector is the signal at the first input terminal.

When the external control signal is at a high level, the signal at the output terminal of the first selector is the signal at the second input terminal.

According to some embodiments of the first aspect of the present disclosure, the current module includes a plurality of second signal processing subcircuits that are in one-to-one correspondence with the power stage chips in the current module.

The second signal processing subcircuit includes a second operational transconductance amplifier, a fifth resistor, a sixth resistor, a seventh resistor, a second current source, and a second signal processing unit. A positive input terminal of the second operational transconductance amplifier is grounded through the fifth resistor. Both the positive input terminal of the first operational transconductance amplifier and the fifth resistor serve as a first current input terminal of the second signal processing subcircuit, and the first current input terminal is connected to the current detection pin of a corresponding power stage chip in the current module. An inverting input terminal of the second operational transconductance amplifier is grounded through the sixth resistor. Both the inverting input terminal of the second operational transconductance amplifier and the sixth resistor serve as a second current input terminal of the second signal processing subcircuit, and the second current input terminal is connected to the current detection pin of a corresponding power stage chip. An output terminal of the second operational transconductance amplifier is grounded through the seventh resistor. An output terminal of the second current source and a voltage input terminal of the second signal processing unit are connected to a net between the seventh resistor and the output terminal of the second operational transconductance amplifier. The output terminal of the second signal processing unit serves as the pulse output terminal corresponding to the target current detection terminal, and a signal input terminal of the second signal processing unit is connected to a signal output terminal of the second signal processing unit.

The second signal processing unit is configured to increase or reduce the duty cycle of an output signal at the signal output terminal of the second signal processing unit based on a voltage across the seventh resistor.

According to some embodiments of the first aspect of the present disclosure, the second signal processing unit includes a sixth field effect transistor, a seventh field effect transistor, an eighth field effect transistor, a ninth field effect transistor, a tenth field effect transistor, and an eighth resistor. A gate of the sixth field effect transistor serves as a signal input terminal of the first signal processing unit. The gate of the sixth field effect transistor is connected to a gate of the seventh field effect transistor. A drain of the sixth field effect transistor is connected to a drain of the seventh field effect transistor, and a source of the seventh field effect transistor is grounded. One end of the eighth resistor is connected to a source of the sixth field effect transistor, and the other end of the eighth resistor serves as a voltage input terminal of the first signal processing unit. One end of the first capacitor is connected to a drain of the seventh field effect transistor, and the other end of the first capacitor is grounded. A gate of the eighth field effect transistor is connected to a gate of the seventh field effect transistor. A source of the eighth field effect transistor is grounded, and a source of the eighth field effect transistor is connected to the drain of the seventh field effect transistor, a gate of the ninth field effect transistor, and a gate of the tenth field effect transistor. A source of the ninth field effect transistor is grounded, and a drain of the ninth field effect transistor is connected to a drain of the tenth field effect transistor. A source of the tenth field effect transistor is connected to a supply voltage.

According to some embodiments of the first aspect of the present disclosure, the resistance of the second resistor is N times that of the first resistor, where N is the number of the current detection terminals.

According to some embodiments of the first aspect of the present disclosure, the resistance of the sixth resistor is X times that of the fifth resistor, where X is the number of power stage chips in the current module.

In an embodiment of a second aspect of the present disclosure, a circuit board may include a parallel circuit architecture for multi-phase power stage chips according to any one of the embodiments of the first aspect.

In an embodiment of a third aspect of the present disclosure, an electronic device may include the circuit board according to the embodiments of the second aspect.

Additional aspects and advantages of the present disclosure will be partly given in the following description, partly become apparent from the following description, or be learned through the practice of the present disclosure.

### BRIEF DESCRIPTION OF DRAWINGS

The present disclosure will be further described below with reference to the accompanying drawings and embodiments.

FIG. 1 is a schematic structural diagram of a parallel circuit architecture for a plurality of multi-phase power stage chips according to an embodiment of the present disclosure;

FIG. 2 is a schematic structural diagram of a power stage chip according to an embodiment of the present disclosure;

FIG. 3 is a schematic structural diagram of a first signal processing subcircuit according to an embodiment of the present disclosure;

FIG. 4 is a schematic structural diagram of a first signal processing unit according to an embodiment of the present disclosure;

FIG. 5 is a timing diagram of PWM and PWMO according to an embodiment of the present disclosure; and

FIG. 6 is a schematic diagram of signals at PWM1, PWM2, PWM3, and PWM4 in FIG. 1.

### DETAILED DESCRIPTION

Embodiments of the present disclosure will be described in detail below. Examples of the embodiments are shown in the accompanying drawings, where the same or similar reference numerals indicate the same or similar elements or elements having the same or similar functionalities. The embodiments described below with reference to the accompanying drawings are exemplary and are merely intended to explain the present disclosure, and should not be construed as limiting the present disclosure.

In the description herein, it should be understood that terms of orientation or positional relationship, such as up, down, front, back, left, right, etc., are based on the orientation or positional relationship shown in the accompanying drawings, and are used merely for the convenience of describing the present disclosure and simplifying the description. They should not be construed as indicating or implying that the device or element referred to must have a specific orientation, be constructed and operated in a specific orientation, and therefore should not be understood as a limitation on the present disclosure.

In the description herein, the term “several” means more than one, the term “a plurality of” means more than two, and the terms “greater than”, “less than”, “exceed”, etc. are understood to exclude the number subsequent to said terms, while the terms “above”, “below”, “within”, etc. are understood to include the number subsequent to said terms. The use of terms such as “first” and “second” is merely for the purpose of distinguish technical features and should not be understood as indicating or implying relative importance. Further such terms should not be understood as specifying the quantity of the technical features indicated or as implying a sequence of the technical features indicated.

In the description herein, terms such as “provided”, “mounted”, “connected” etc. should be understood in a broad sense, unless otherwise clearly defined. A person skilled in the art can reasonably determine the specific meanings of these terms in this application based on the specific content of the technical solution.

In the description herein, the content described in conjunction with terms such as “one embodiment”, “some embodiments”, “illustrative embodiment”, “example”, “specific example”, and “some example” indicates that the specific features, structures, materials or characteristics described in conjunction with said embodiment(s) or example(s) are included in at least one embodiment or example of the present disclosure. The exemplary expressions of the above terms do not necessarily refer to the same embodiment or example. Further, the specific features, structures, materials, or characteristics described herein may be combined in any suitable manner in any one or more embodiments or examples.

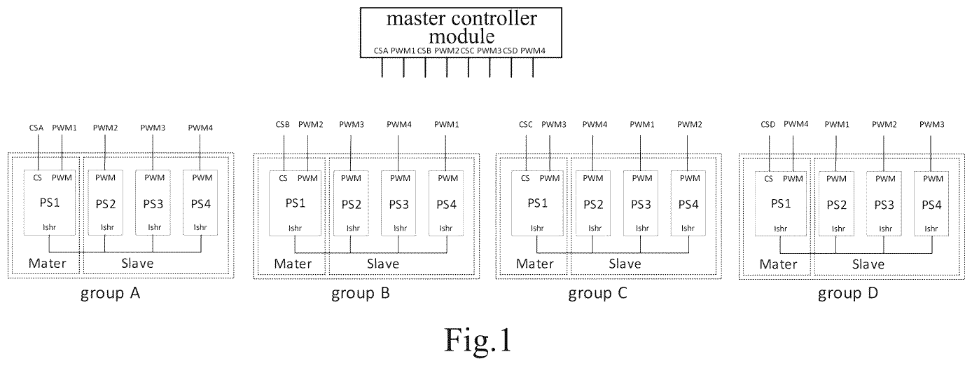

In an embodiment of a first aspect of the present disclosure, a parallel circuit architecture for multi-phase power stage chips is provided. Referring to FIG. 1, a schematic diagram showing a structure of a parallel circuit architecture for a plurality of multi-phase power stage chips according to an embodiment of the present disclosure is illustrated. The parallel circuit architecture for the plurality of multi-phase power stage chips in this embodiment of the present disclosure includes a master controller module and a plurality of current modules. The master controller module has a plurality of current detection terminals and a plurality of pulse output terminals, and the number of the current detection terminals is in one-to-one correspondence with that of the pulse output terminals. The current detection terminals are in one-to-one correspondence with the current modules. Each current module includes a plurality of power stage chips, and the number of pulse output terminals is equal to that of power stage chips in one current module. The control terminal of each power stage chip in the current module is connected to the pulse output terminal in one-to-one correspondence. Current sharing pins of respective power stage chips in the current module are connected to one another. The current detection terminals are each connected to a current detection pin of one of the power stage chips in a corresponding current module. Further, the power stage chips in the respective current modules, which are connected to the current detection terminals, are connected to different pulse output terminals.

The master controller module is configured to: output pulse signals through the respective pulse output terminals, and detect currents of the power stage chips through the current detection terminals; reduce the duty cycle of a pulse signal at a pulse output terminal connected to a power stage chip connected to a target current detection terminal in response to detecting that the current at the target current detection terminal is greater than the currents at the remaining current detection terminals; increase the duty cycle of the pulse signal at the pulse output terminal connected to the power stage chip connected to the target current detection terminal in response to detecting that the current of the target current detection terminal is less than the currents at the remaining current detection terminals.

Specifically, in the circuit architecture according to the embodiments of the present disclosure, the current modules are connected in parallel, and the power stage chips in each current module are connected in parallel. The pulse output terminals of the master controller module output pulse signals. Because the control terminal of each power stage chip in the current module is connected to the pulse output terminal in one-to-one correspondence, each power stage chip in the current module is in one-to-one correspondence with a pulse signal. The current detection terminal is connected to a current detection pin of one of the power stage chips in a corresponding current module. Further, the power stage chips in the respective current modules, which are connected to the current detection terminals, are connected to different pulse output terminals. A target current detection terminal is any one of the plurality of current detection terminals. When it is detected that the current at the target current detection terminal is greater than the currents at the remaining current detection terminals, it indicates that the output current of the power stage chip connected to the target current detection terminal is greater than the currents of the remaining power stage chips. The current is primarily related to the duty cycle of the pulse signal. That is, the duty cycle of the pulse signal connected to the power stage chip connected to the target current detection terminal is excessively high. A target pulse signal is the pulse signal connected to the power stage chip connected to the target current detection terminal, and the current of each power stage chip connected to the target pulse signal is excessively high. Therefore, the duty cycle of the target pulse signal is reduced to equalize the current across each power stage chip. When it is detected that the current at the target current detection terminal is less than the currents at the remaining current detection terminals, it indicates that the duty cycle of the target pulse signal is excessively low, and accordingly, the duty cycle of the target pulse signal is increased to equalize the current across each power stage chip. In this way, the output currents of the power stage chips connected in parallel are equalized, thereby ensuring circuit stability and improving service life. In addition, in the present disclosure, a single pulse signal controls the plurality of power stage chips, thereby saving pins of the master controller module.

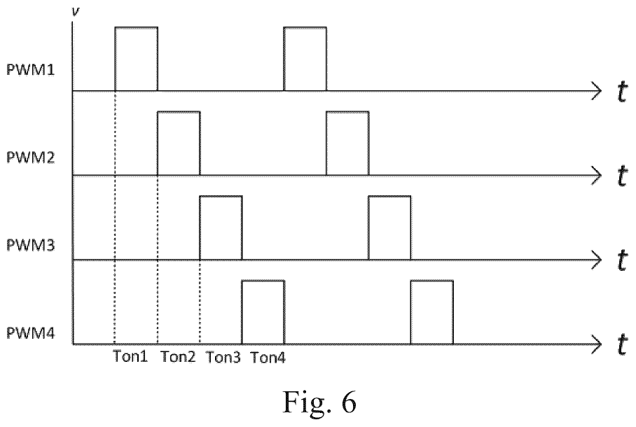

Exemplarily, referring to FIG. 1, there are four current modules i.e., group A, group B, group C, and group D. The number of power stage chips in the current module is four. In one current module, the four power stage chips are PS1, PS2, PS3, and PS4. The master controller module has four pulse output terminals i.e., PWM1, PWM2, PWM3, and PWM4, and four current detection terminals i.e., CSA, CSB, CSC, and CSD. For example, when an overcurrent is detected at the CSA, it indicates that the output current of PS1 in group A is excessive, that is, the duty cycle of the pulse signal at the PWM1 is excessively high. Consequently, output currents of PS4 in group B, PS3 in group C, and PS2 in group D are also excessive. Accordingly, the master controller module reduces the duty cycle of the pulse signal output by PWM1 to in turn reduce the currents of PS1 in group A, PS4 in group B, PS3 in group C, and PS2 in group D, thereby equalizing the output currents of all power stage chips. Referring to FIG. 6, a schematic diagram of signals at PWM1, PWM2, PWM3, and PWM4 in FIG. 1 is illustrated.

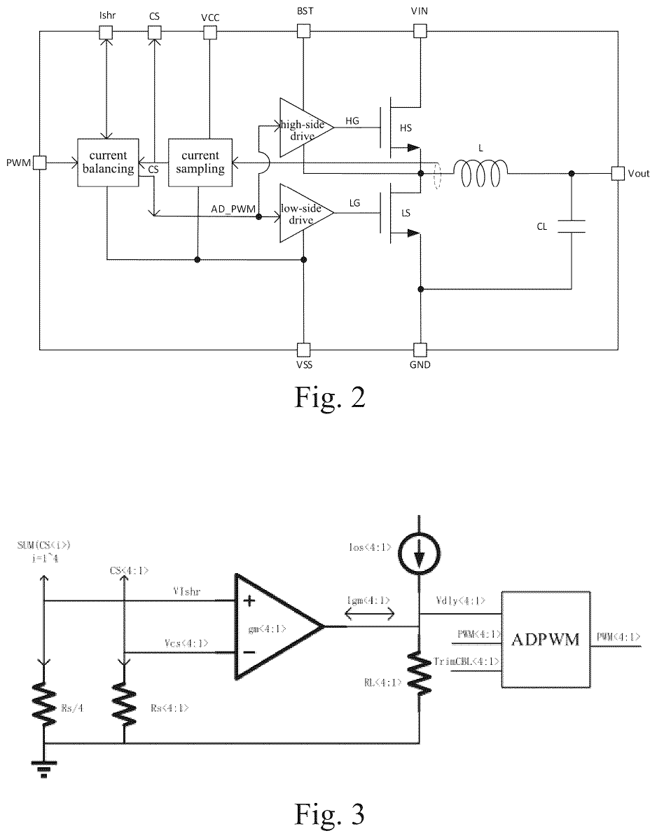

It should be noted that the models of the power stage chips are identical. The output current of the power stage chip is a function of the duty cycle of the pulse signal. The higher the duty cycle of the pulse signal, the greater the output current of the power stage chip to which the pulse signal is connected. In the current module, current sharing pins of respective power stage chips are connected to one another. Referring to FIG. 2, a schematic diagram showing a structure of a power stage chip according to an embodiment of the present disclosure is illustrated. The power stage chip includes a current balancing unit, a current sampling unit, a high-side driver, a low-side driver, a high-side power transistor, and a low-side power transistor, and further includes a capacitor CL and an inductor L. The current balancing unit received a pulse signal is configured to control the high-side driver and the low-side driver based on the pulse signal. The current sampling unit is configured to sample an output current of the power stage chip and transmit the output current to the current balancing unit. The current balancing unit has a current sharing pin. In FIGS. 1 and 2, Ishr is a current sharing pin, and CS is a current detection pin. In a multi-phase parallel power supply system, an Ishr pin achieves current balancing among phases by being connected to a specific resistor (typically 3 kΩ). This ensures even current distribution across all phases, thereby preventing some phases from being overloaded while others are underloaded. The high-side driver is connected to a gate of the high-side power transistor, and the low-side driver is connected to a gate of the low-side power transistor. The high-side power transistor is HS, and the low-side power transistor is LG. A source of the high-side power transistor is connected to an input voltage VIN, and a source of the low-side power transistor is grounded. A drain of the low-side power transistor is connected to a drain of the high-side power transistor. One end of the inductor L is connected between the low-side power transistor and the high-side power transistor, and the other end thereof serves as an output terminal Vout of the power stage chip and is grounded through the capacitor CL. The present disclosure does not provide specific limitations on the structures of the current balancing unit and the current sampling unit. The power stage chip shown in FIG. 2 is merely an example. The power stage chip may also include other electrical components, and the present disclosure does not provide specific limitations thereon.

It should be noted that the number of current modules and the number of power stage chips shown in FIG. 1 are merely exemplary and should not be construed as limitations on the present disclosure.

It can be understood that, referring to FIG. 3, a schematic diagram showing a structure of a first signal processing subcircuit according to an embodiment of the present disclosure is illustrated. The master controller module includes a plurality of first signal processing subcircuits that are in one-to-one correspondence with the pulse output terminals.

The first signal processing subcircuit includes a first operational transconductance amplifier, a first resistor, a second resistor, a third resistor, a first current source, and a first signal processing unit. A positive input terminal of the first operational transconductance amplifier is grounded through the first resistor. Both the positive input terminal of the first operational transconductance amplifier and the first resistor serve as a first current input terminal of the first signal processing subcircuit. The first current input terminal is connected to a corresponding current detection terminal. An inverting input terminal of the first operational transconductance amplifier is grounded through the second resistor. Both the inverting input terminal of the first operational transconductance amplifier and the second resistor serve as a second current input terminal of the first signal processing subcircuit. The second current input terminal is connected to a target current detection terminal. An output terminal of the first operational transconductance amplifier is grounded through the third resistor. An output terminal of the first current source and a voltage input terminal of the first signal processing unit are connected to the net between the third resistor and the output terminal of the first operational transconductance amplifier. An output terminal of the first signal processing unit serves as a pulse output terminal corresponding to the target current detection terminal. A signal input terminal of the first signal processing unit is connected to a signal output terminal of the first signal processing unit.

The first signal processing unit is configured to increase or reduce the duty cycle of an output signal at the signal output terminal of the first signal processing unit based on a voltage across the third resistor.

It should be noted that the resistance of the first resistor is N times that of the second resistor, where N is the number of current detection terminals. In FIG. 1, N is four, that is, the resistance of the second resistor is four times that of the first resistor. Referring to FIG. 3, the first resistor is Rs/4, the second resistor is Rs<4:1>, SUM(CS<i>) represents the first current input terminal of the first signal processing subcircuit, and CS<4:1> represents the second current input terminal of the first signal processing subcircuit. The current at the SUM(CS<i>) terminal is a sum of currents at CSA, CSB, CSC, and CSD. The current at the CS<4:1> terminal is a current at one of CSA, CSB, CSC, and CSD. gm<4:1> is the first operational transconductance amplifier, Ios<4:1> is the first current source. RL<4:1> is the third resistor. ADPWM is the first signal processing unit, and Vdly<4:1> represents a voltage across RL. PWM<4:1> represents a pulse signal at one of PWM1, PWM2, PWM3, and PWM4. Igm<4:1> represents an output current of the first operational transconductance amplifier. VIshr represents a voltage across the first resistor, and Vcs<4:1> represents a voltage across the second resistor. ADPWM is the first signal processing unit.

Specifically, for example, CS<4:1> is a current at CSA. If VIshr is greater than Vcs, it indicates that an average current at CSA, CSB, CSC, and CSD is greater than the current at CSA, that is, an average of the currents of PS1 in group A, PS1 in group B, PS1 in group C, and PS1 in group D is greater than the current of PS1 in group A. In this case, Igm<4:1> is a negative value, and Vdly<4:1> decreases. Accordingly, the duty cycle of the output signal at the signal output terminal of the first signal processing unit is increased, that is, the duty cycle of the pulse signal at the PWM1 terminal connected to PS1 in group A is increased.

If VIshr is less than Vcs, it indicates that the average current at CSA, CSB, CSC, and CSD is less than the current at the CSA terminal, that is, the average of the currents of PS1 in group A, PS1 in group B, PS1 in group C, and PS1 in group D is less than the current of PS1 in group A. In this case, Igm<4:1> is a positive value, and Vdly<4:1> increases. Accordingly, the duty cycle of the output signal at the signal output terminal of the first signal processing unit is decreased, that is, the duty cycle of the pulse signal at the PWM1 terminal connected to PS1 in group A is reduced.

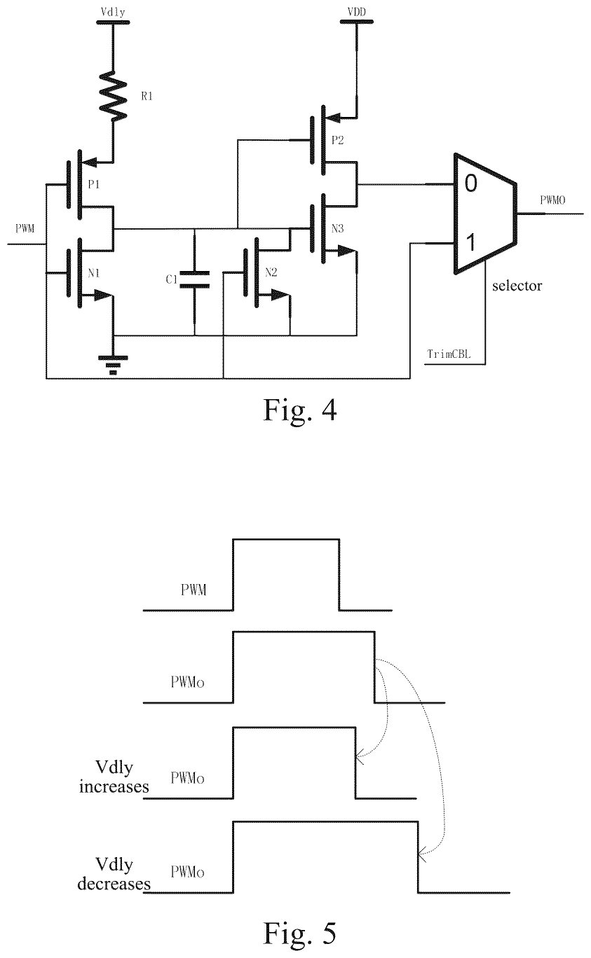

It can be understood that, referring to FIG. 4, a schematic diagram showing a structure of a first signal processing unit in an embodiment of the present disclosure is illustrated. The first signal processing unit includes a first field effect transistor, a second field effect transistor, a third field effect transistor, a fourth field effect transistor, a fifth field effect transistor, and a fourth resistor. A gate of the first field effect transistor serves as a signal input terminal of the first signal processing unit, and the gate of the first field effect transistor is connected to a gate of the second field effect transistor. A drain of the first field effect transistor is connected to a drain of the second field effect transistor, and a source of the second field effect transistor is grounded. One end of the fourth resistor is connected to the source of the first field effect transistor, and the other end thereof serves as a voltage input terminal of the first signal processing unit. One end of the first capacitor is connected to the drain of the second field effect transistor, and the other end thereof is grounded. The gate of the third field effect transistor is connected to the gate of the second field effect transistor, and the source of the third field effect transistor is grounded. The source of the third field effect transistor is connected to the drain of the second field effect transistor, a gate of the fourth field effect transistor, and a gate of the fifth field effect transistor. A source of the fourth field effect transistor is grounded, and a drain of the fourth field effect transistor is connected to a drain of the fifth field effect transistor. A source of the fifth field effect transistor is connected to a supply voltage.

Specifically, in FIG. 4, the first field effect transistor is P1. The second field effect transistor is N1. The third field effect transistor is N2. The fourth field effect transistor is N3. The fifth field effect transistor is P2. The first capacitor is C1, and the fourth resistor is R1. In FIG. 4, PWM represents a pulse signal at one of PWM1, PWM2, PWM3, and PWM4, and PWMO represents a processed pulse signal. Referring to FIG. 5, a timing diagram of PWM and PWMO according to an embodiment of the present disclosure is illustrated. When PWM is rising, N2 turns on rapidly, causing N3 to turn on rapidly, and the rising edge of a PWM signal has a negligible delay. When PWM is falling, P1 turns on, Vdly and R1 generate a current for charging the first capacitor C1, and the voltage across C1 gradually increases. When the voltage across the first capacitor rises to a threshold voltage of N3, N3 turns on. The charging current can be modified by adjusting the magnitude of Vdly, thereby altering the charging time i.e., the delay time, for the first capacitor, so as to alter the duty cycle of PWM. When Vdly increases, the charging current rises, resulting to faster charging and a reduced delay time, thereby reducing the duty cycle of the output PWMO. Conversely, when Vdly decreases, the charging current reduces, resulting to slower charging and an increased delay time, thereby increasing the duty cycle of the output PWMO.

In some other embodiments, the power stage chips in the current module can be connected to an identical PWM signal.

In an embodiment, referring to FIG. 4, the first signal processing unit further includes a first selector. A first input terminal of the first selector is connected to the drain of the fourth field effect transistor, and a second input terminal of the first selector is connected to the gate of the first field effect transistor. The first selector also receives an external control signal, and an output terminal of the first selector serves as the signal output terminal of the first signal processing unit.

When the external control signal is at a low level, the signal at the output terminal of the first selector is the signal at the first input terminal.

When the external control signal is at a high level, the signal at the output terminal of the first selector is the signal at the second input terminal.

Specifically, TrimCBL is an external control signal. Generally, in the first signal processing unit, the external control signal is at a low level.

In an embodiment, the current module includes a plurality of second signal processing subcircuits that are in one-to-one correspondence with the power stage chips in the current module. It should be noted that the second signal processing subcircuit can be disposed within or externally to the power stage chip. When the second signal processing subcircuit is disposed within the power stage chip, the second signal processing subcircuit serves as a current balancing unit of the power stage chip.

The second signal processing subcircuit includes a second operational transconductance amplifier, a fifth resistor, a sixth resistor, a seventh resistor, a second current source, and a second signal processing unit. A positive input terminal of the second operational transconductance amplifier is grounded through the fifth resistor. Both the positive input terminal of the second operational transconductance amplifier and the fifth resistor serve as a first current input terminal of the second signal processing subcircuit. The first current input terminal is connected to the current detection pin of each power stage chip in a current module. An inverting input terminal of the second operational transconductance amplifier is grounded through the sixth resistor. Both the inverting input terminal of the second operational transconductance amplifier and the sixth resistor serve as a second current input terminal of the second signal processing subcircuit. The second current input terminal is connected to the current detection pin of a corresponding power stage chip. An output terminal of the second operational transconductance amplifier is grounded through the seventh resistor. An output terminal of the second current source and a voltage input terminal of the second signal processing unit are connected to the net between the seventh resistor and the output terminal of the second operational transconductance amplifier. Further, an output terminal of the second signal processing unit serves as a pulse output terminal corresponding to a target current detection terminal, and a signal input terminal of the second signal processing unit is connected to a signal output terminal of the second signal processing unit.

The second signal processing unit is configured to increase or reduce the duty cycle of an output signal at the signal output terminal of the second signal processing unit based on a voltage across the seventh resistor.

The second signal processing unit includes a sixth field effect transistor, a seventh field effect transistor, an eighth field effect transistor, a ninth field effect transistor, a tenth field effect transistor, and an eighth resistor. A gate of the sixth field effect transistor serves as a signal input terminal of the first signal processing unit. The gate of the sixth field effect transistor is connected to a gate of the seventh field effect transistor. A drain of the sixth field effect transistor is connected to a drain of the seventh field effect transistor, and a source of the seventh field effect transistor is grounded. One end of the eighth resistor is connected to a source of the sixth field effect transistor, and the other end thereof serves as a voltage input terminal of the first signal processing unit. One end of the first capacitor is connected to a drain of the seventh field effect transistor, and the other end thereof is grounded. A gate of the eighth field effect transistor is connected to the gate of the seventh field effect transistor. A source of the eighth field effect transistor is grounded, and the source of the eighth field effect transistor is connected to the drain of the seventh field effect transistor, a gate of the ninth field effect transistor, and a gate of the tenth field effect transistor. A source of the ninth field effect transistor is grounded, and a drain of the ninth field effect transistor is connected to a drain of the tenth field effect transistor. A source of the tenth field effect transistor is connected to a supply voltage.

The resistance of the sixth resistor is X times that of the fifth resistor, where X is the number of power stage chips in the current module.

The second signal processing unit further includes a second selector. A first input terminal of the second selector is connected to the drain of the ninth field effect transistor. A second input terminal of the second selector is connected to the gate of the first field effect transistor.

The second selector also receives an external control signal. An output terminal of the second selector serves as a signal output terminal of the second signal processing unit. The signal output terminal of the second signal processing unit is connected to the control terminal of the power stage chip to control the operation of the high-side power transistor and the low-side power transistor.

When the external control signal is at a low level, the signal at the output terminal of the second selector is the signal at the first input terminal.

When the external control signal is at a high level, the signal at the output terminal of the second selector is the signal at the second input terminal.

For example, the number of power stage chips in the current module is four, and therefore X is four. The number of second signal processing subcircuits is four. The first field effect transistor is identical to the sixth field effect transistor. The second field effect transistor is identical to the seventh field effect transistor. The third field effect transistor is identical to the eighth field effect transistor. The fourth field effect transistor is identical to the ninth field effect transistor. The fifth field effect transistor is identical to the tenth field effect transistor. The first resistor is identical to the fifth resistor. The second resistor is identical to the sixth resistor. The third resistor is equivalent to the seventh resistor. The fourth resistor is equivalent to the eighth resistor. The first current source is identical to the second current source. The first operational transconductance amplifier is identical to the second operational transconductance amplifier. The first selector is identical to the second selector. Therefore, the structure and principle of the second signal processing subcircuit are identical to those of the first signal processing subcircuit, and thus will not be described in detail here.

In an embodiment, referring to FIG. 1, a current detection pin of one of the power stage chips in each current module is connected to a current detection terminal of the master controller module, and said power stage chip is a master chip, while other power stage chips in the current module are slave chips. In each current module, PS1 is a master chip, and PS2 to PS4 are slave chips. In the second signal processing subcircuit, if a power stage chip corresponding to a second signal processing subcircuit is a master chip, the external control signal of the second selector in the second signal processing subcircuit is at a high level. That is, the current module does not process the pulse signal received by the master chip, and directly uses the pulse signal output by the master controller module to control the operation of the master chip, thereby ensuring the stability of a system. In a second signal processing subcircuit corresponding to a slave chip, the external control signal of the second selector is at a low level.

In another embodiment, no matter whether the power stage chip corresponding to the second signal processing subcircuit is a master chip or a slave chip, the external control signal of the second selector is at a low level. Further, those having ordinary skill in the art can set the level of the external control signal as required.

In some embodiments, the current detection pin of the master chip in the current module is connected to the current detection pin of at least one slave chip, such that the current input to the current detection terminal of the master controller module is a sum of the output current of the master chip and the output current of at least one slave chip. For example, in each current module, the current output pins of PS1, PS2, PS3, and PS4 are connected to one another, and thus the current at the current detection terminal connected to the current module (i.e., current CS<4:1>) is the sum of the output currents of PS1, PS2, PS3, and PS4. SUM(CS<i>) is the sum of four CS<4:1>. For example, CS<4:1> is the sum of the output currents of PS1, PS2, PS3, and PS4 in group A. If Vcs<4:1> is greater than VIshr, it indicates that the total output current of group A is greater than the average of the total output currents of group A, group B, group C, and group D. Because the master chip PS1 in group A is received the pulse signal at the PWM1 terminal, the duty cycle of the pulse signal at the PMW1 terminal is reduced to in turn reduce the total output current of group A.

If Vcs<4:1> is less than VIshr, it indicates that the total output current of group A is less than the average of the total output currents of group A, group B, group C and group D. Because the master chip PS1 in group A is received the pulse signal at the PWM1 terminal, the duty cycle of the pulse signal at the PMW1 terminal is increased to increase the total output current of group A.

In an embodiment of a second aspect of the present disclosure, a circuit board may include a parallel circuit architecture for multi-phase power stage chips according to the embodiments of the first aspect.

Because the circuit board includes the parallel circuit architecture for multi-phase power stage chips according to the embodiments of the first aspect, the content corresponding to the parallel circuit architecture for multi-phase power stage chips in the embodiments of the first aspect is also applicable to the circuit board in the embodiments of the second aspect, and the implementation principle and technical effect are also identical, which will not be described in detail here for brevity.

In an embodiment of a third aspect of the present disclosure, an electronic device may include a circuit board according to the embodiments of the second aspect.

The electronic device includes the circuit board according to the embodiments of the second aspect, and the circuit board includes the parallel circuit architecture for multi-phase power stage chips according to the embodiments of the first aspect. Therefore, the content corresponding to the parallel circuit architecture for multi-phase power stage chips in the embodiments of the first aspect is also applicable to the electronic device in the embodiments of the third aspect, and the implementation principle and technical effect are identical, which will not be described in detail here for brevity.

The embodiments of the present disclosure are described in detail above in conjunction with the accompanying drawings, but the present disclosure is not limited thereto. Various modifications can be made within the scope of knowledge possessed by those skilled in the art without departing from the gist of the present disclosure. In addition, the embodiments of the present disclosure and the features therein may be combined with one another unless there is any conflict.

What is claimed is:

1. A parallel circuit architecture for a plurality of multi-phase power stage chips, comprising:
a master controller module, comprising a plurality of current detection terminals and a plurality of pulse output terminals, wherein the number of the plurality of current detection terminals is one-to-one correspondence with the number of the plurality of pulse output terminals; and
a plurality of current modules one-to-one corresponding to the plurality of current detection terminals, wherein each of the plurality of current modules comprises a plurality of power stage chips, the number of the plurality of pulse output terminals is equal to the number of the plurality of power stage chips in one of the plurality of current modules, and a control terminal of each of the plurality of power stage chips in each of the plurality of current modules is connected to one of the plurality of pulse output terminal in one-to-one correspondence,
wherein the plurality of current detection terminals are each connected to a current detection pin of one of the plurality of power stage chips in a corresponding current module, and the plurality of power stage chips in the respective current modules, which are connected to plurality of the current detection terminals, are connected to different pulse output terminals; and
the master controller module is configured to:
output a pulse signal through the respective pulse output terminals, and detect currents of corresponding power stage chips through the plurality of current detection terminals connected to the master controller module;
in response to detecting that the current at a target current detection terminal is greater than the current at the remaining current detection terminals, reduce a duty cycle of a pulse signal at a pulse output terminal connected to a power stage chip connected to the target current detection terminal; and
in response to detecting that the current at the target current detection terminal is less than the current at the remaining current detection terminals, increase the duty cycle of the pulse signal at the pulse output terminal connected to the power stage chip connected to the target current detection terminal.

2. The parallel circuit architecture for the plurality of multi-phase power stage chips according to claim 1, wherein the master controller module comprises a plurality of first signal processing subcircuits that are in one-to-one correspondence with the plurality of pulse output terminals, wherein
the first signal processing subcircuit comprises a first operational transconductance amplifier, a first resistor, a second resistor, a third resistor, a first current source, and a first signal processing unit, wherein a positive input terminal of the first operational transconductance amplifier is grounded through the first resistor, both the positive input terminal of the first operational transconductance amplifier and the first resistor serve as a first current input terminal of the first signal processing subcircuit, and the first current input terminal is connected to a corresponding current detection terminal; an inverting input terminal of the first operational transconductance amplifier is grounded through the second resistor, both the inverting input terminal of the first operational transconductance amplifier and the second resistor serve as a second current input terminal of the first signal processing subcircuit, and the second current input terminal is connected to the target current detection terminal; an output terminal of the first operational transconductance amplifier is grounded through the third resistor; an output terminal of the first current source and a voltage input terminal of the first signal processing unit are connected to a net between the third resistor and the output terminal of the first operational transconductance amplifier; and an output terminal of the first signal processing unit serves as the pulse output terminal corresponding to the target current detection terminal, and a signal input terminal of the first signal processing unit is connected to a signal output terminal of the first signal processing unit; and
the first signal processing unit is configured to increase or reduce the duty cycle of an output signal at the signal output terminal of the first signal processing unit based on a voltage across the third resistance.

3. The parallel circuit architecture for the plurality of multi-phase power stage chips according to claim 2, wherein the first signal processing unit comprises a first field effect transistor, a second field effect transistor, a third field effect transistor, a fourth field effect transistor, a fifth field effect transistor, and a fourth resistor, wherein a gate of the first field effect transistor P1 serves as the signal input terminal of the first signal processing unit, the gate of the first field effect transistor is connected to a gate of the second field effect transistor N1, a drain of the first field effect transistor is connected to a drain of the second field effect transistor, and a source of the second field effect transistor is grounded; one end of the fourth resistor is connected to a source of the first field effect transistor, and the other end of the fourth resistor serves as a voltage input terminal of the first signal processing unit; one end of the first capacitor is connected to the drain of the second field effect transistor, and the other end of the first capacitor is grounded; a gate of the third field effect transistor N2 is connected to the gate of the second field effect transistor, a source of the third field effect transistor is grounded, and the source of the third field effect transistor is connected to the drain of the second field effect transistor, a gate of the fourth field effect transistor N3, and a gate of the fifth field effect transistor P2; a source of the fourth field effect transistor is grounded, and a drain of the fourth field effect transistor is connected to a drain of the fifth field effect transistor; and a source of the fifth field effect transistor is connected to a supply voltage.

4. The parallel circuit architecture for the plurality of multi-phase power stage chips according to claim 3, wherein the first signal processing unit further comprises a first selector; a first input terminal of the first selector is connected to the drain of the fourth field effect transistor; and a second input terminal of the first selector is connected to the gate of the first field effect transistor; the first selector is configured to receive an external control signal, and an output terminal of the first selector serves as the signal output terminal of the first signal processing unit,
wherein in response to the external control signal being at a low level, the signal at the output terminal of the first selector is the signal at the first input terminal; and
in response to the external control signal being at a high level, the signal at the output terminal of the first selector is the signal at the second input terminal.

5. The parallel circuit architecture for the plurality of multi-phase power stage chips according to claim 1, wherein each of the plurality of current modules comprises a plurality of second signal processing subcircuits that are in one-to-one correspondence with the plurality of power stage chips in the corresponding current module,
wherein the second signal processing subcircuit comprises a second operational transconductance amplifier, a fifth resistor, a sixth resistor, a seventh resistor, a second current source, and a second signal processing unit, wherein a positive input terminal of the second operational transconductance amplifier is grounded through the fifth resistor, both the positive input terminal of the first operational transconductance amplifier and the fifth resistor serve as a first current input terminal of the second signal processing subcircuit, and the first current input terminal is connected to the current detection pin of a corresponding power stage chip in the plurality of current modules; an inverting input terminal of the second operational transconductance amplifier is grounded through the sixth resistor, and both the inverting input terminal of the second operational transconductance amplifier and the sixth resistor serve as a second current input terminal of the second signal processing subcircuit, and the second current input terminal is connected to a current detection pin of a corresponding power stage chip; an output terminal of the second operational transconductance amplifier is grounded through the seventh resistor; an output terminal of the second current source and a voltage input terminal of the second signal processing unit are connected to a net between the seventh resistor and the output terminal of the second operational transconductance amplifier, the output terminal of the second signal processing unit serves as the pulse output terminal corresponding to the target current detection terminal, and a signal input terminal of the second signal processing unit is connected to a signal output terminal of the second signal processing unit; and
the second signal processing unit is configured to increase or reduce the duty cycle of an output signal at the signal output terminal of the second signal processing unit based on a voltage across the seventh resistor.

6. The parallel circuit architecture for the plurality of multi-phase power stage chips according to claim 5, wherein the second signal processing unit comprises a sixth field effect transistor, a seventh field effect transistor, an eighth field effect transistor, a ninth field effect transistor, a tenth field effect transistor, and an eighth resistor, wherein a gate of the sixth field effect transistor serves as a signal input terminal of the first signal processing unit, the gate of the sixth field effect transistor is connected to a gate of the seventh field effect transistor, a drain of the sixth field effect transistor is connected to a drain of the seventh field effect transistor, and a source of the seventh field effect transistor is grounded; one end of the eighth resistor is connected to a source of the sixth field effect transistor, and the other end of the eighth resistor serves as a voltage input terminal of the first signal processing unit; one end of the first capacitor is connected to the drain of the seventh field effect transistor, and the other end of the first capacitor is grounded; a gate of the eighth field effect transistor is connected to a gate of the seventh field effect transistor, a source of the eighth field effect transistor is grounded, and a source of the eighth field effect transistor is connected to the drain of the seventh field effect transistor, a gate of the ninth field effect transistor, and a gate of the tenth field effect transistor; a source of the ninth field effect transistor is grounded, and a drain of the ninth field effect transistor is connected to a drain of the tenth field effect transistor; and a source of the tenth field effect transistor is connected to a supply voltage.

7. The parallel circuit architecture for the plurality of multi-phase power stage chips according to claim 2, wherein the resistance of the second resistor is N times the resistance of the first resistor, and wherein N is the number of the plurality of current detection terminals.

8. The parallel circuit architecture for the plurality of multi-phase power stage chips according to claim 5, wherein the resistance of the sixth resistor is X times the resistance of the fifth resistor, and wherein X is the number of the plurality of power stage chips in the corresponding current module.

9. A circuit board, comprising a parallel circuit architecture for a plurality of multi-phase power stage chips which comprises:
a master controller module, comprising a plurality of current detection terminals and a plurality of pulse output terminals, wherein the number of the plurality of current detection terminals is one-to-one correspondence with the number of the plurality of pulse output terminals; and
a plurality of current modules one-to-one corresponding to the plurality of current detection terminals, wherein each of the plurality of current modules comprises a plurality of power stage chips, the number of the plurality of pulse output terminals is equal to the number of the plurality of power stage chips in one of the plurality of current modules, and a control terminal of each of the plurality of power stage chips in each of the plurality of current modules is connected to one of the plurality of pulse output terminal in one-to-one correspondence,
wherein the plurality of current detection terminals are each connected to a current detection pin of one of the plurality of power stage chips in a corresponding current module, and the plurality of power stage chips in the respective current modules, which are connected to plurality of the current detection terminals, are connected to different pulse output terminals; and
the master controller module is configured to:
output a pulse signal through the respective pulse output terminals, and detect currents of corresponding power stage chips through the plurality of current detection terminals connected to the master controller module;
in response to detecting that the current at a target current detection terminal is greater than the current at the remaining current detection terminals, reduce a duty cycle of a pulse signal at a pulse output terminal connected to a power stage chip connected to the target current detection terminal; and
in response to detecting that the current at the target current detection terminal is less than the current at the remaining current detection terminals, increase the duty cycle of the pulse signal at the pulse output terminal connected to the power stage chip connected to the target current detection terminal.

10. The circuit board according to claim 9, wherein the master controller module comprises a plurality of first signal processing subcircuits that are in one-to-one correspondence with the plurality of pulse output terminals, wherein
the first signal processing subcircuit comprises a first operational transconductance amplifier, a first resistor, a second resistor, a third resistor, a first current source, and a first signal processing unit, wherein a positive input terminal of the first operational transconductance amplifier is grounded through the first resistor, both the positive input terminal of the first operational transconductance amplifier and the first resistor serve as a first current input terminal of the first signal processing subcircuit, and the first current input terminal is connected to a corresponding current detection terminal; an inverting input terminal of the first operational transconductance amplifier is grounded through the second resistor, both the inverting input terminal of the first operational transconductance amplifier and the second resistor serve as a second current input terminal of the first signal processing subcircuit, and the second current input terminal is connected to the target current detection terminal; an output terminal of the first operational transconductance amplifier is grounded through the third resistor; an output terminal of the first current source and a voltage input terminal of the first signal processing unit are connected to a net between the third resistor and the output terminal of the first operational transconductance amplifier; and an output terminal of the first signal processing unit serves as the pulse output terminal corresponding to the target current detection terminal, and a signal input terminal of the first signal processing unit is connected to a signal output terminal of the first signal processing unit; and
the first signal processing unit is configured to increase or reduce the duty cycle of an output signal at the signal output terminal of the first signal processing unit based on a voltage across the third resistance.

11. The circuit board according to claim 10, wherein the first signal processing unit comprises a first field effect transistor, a second field effect transistor, a third field effect transistor, a fourth field effect transistor, a fifth field effect transistor, and a fourth resistor, wherein a gate of the first field effect transistor P1 serves as the signal input terminal of the first signal processing unit, the gate of the first field effect transistor is connected to a gate of the second field effect transistor N1, a drain of the first field effect transistor is connected to a drain of the second field effect transistor, and a source of the second field effect transistor is grounded; one end of the fourth resistor is connected to a source of the first field effect transistor, and the other end of the fourth resistor serves as a voltage input terminal of the first signal processing unit; one end of the first capacitor is connected to the drain of the second field effect transistor, and the other end of the first capacitor is grounded; a gate of the third field effect transistor N2 is connected to the gate of the second field effect transistor, a source of the third field effect transistor is grounded, and the source of the third field effect transistor is connected to the drain of the second field effect transistor, a gate of the fourth field effect transistor N3, and a gate of the fifth field effect transistor P2; a source of the fourth field effect transistor is grounded, and a drain of the fourth field effect transistor is connected to a drain of the fifth field effect transistor; and a source of the fifth field effect transistor is connected to a supply voltage.

12. The circuit board according to claim 11, wherein the first signal processing unit further comprises a first selector; a first input terminal of the first selector is connected to the drain of the fourth field effect transistor; and a second input terminal of the first selector is connected to the gate of the first field effect transistor; the first selector is configured to receive an external control signal, and an output terminal of the first selector serves as the signal output terminal of the first signal processing unit,
wherein in response to the external control signal being at a low level, the signal at the output terminal of the first selector is the signal at the first input terminal; and
in response to the external control signal being at a high level, the signal at the output terminal of the first selector is the signal at the second input terminal.

13. The circuit board according to claim 9, wherein each of the plurality of current modules comprises a plurality of second signal processing subcircuits that are in one-to-one correspondence with the plurality of power stage chips in the corresponding current module,
wherein the second signal processing subcircuit comprises a second operational transconductance amplifier, a fifth resistor, a sixth resistor, a seventh resistor, a second current source, and a second signal processing unit, wherein a positive input terminal of the second operational transconductance amplifier is grounded through the fifth resistor, both the positive input terminal of the first operational transconductance amplifier and the fifth resistor serve as a first current input terminal of the second signal processing subcircuit, and the first current input terminal is connected to the current detection pin of a corresponding power stage chip in the plurality of current modules; an inverting input terminal of the second operational transconductance amplifier is grounded through the sixth resistor, and both the inverting input terminal of the second operational transconductance amplifier and the sixth resistor serve as a second current input terminal of the second signal processing subcircuit, and the second current input terminal is connected to a current detection pin of a corresponding power stage chip; an output terminal of the second operational transconductance amplifier is grounded through the seventh resistor; an output terminal of the second current source and a voltage input terminal of the second signal processing unit are connected to a net between the seventh resistor and the output terminal of the second operational transconductance amplifier, the output terminal of the second signal processing unit serves as the pulse output terminal corresponding to the target current detection terminal, and a signal input terminal of the second signal processing unit is connected to a signal output terminal of the second signal processing unit; and
the second signal processing unit is configured to increase or reduce the duty cycle of an output signal at the signal output terminal of the second signal processing unit based on a voltage across the seventh resistor.

14. The circuit board according to claim 13, wherein the second signal processing unit comprises a sixth field effect transistor, a seventh field effect transistor, an eighth field effect transistor, a ninth field effect transistor, a tenth field effect transistor, and an eighth resistor, wherein a gate of the sixth field effect transistor serves as a signal input terminal of the first signal processing unit, the gate of the sixth field effect transistor is connected to a gate of the seventh field effect transistor, a drain of the sixth field effect transistor is connected to a drain of the seventh field effect transistor, and a source of the seventh field effect transistor is grounded; one end of the eighth resistor is connected to a source of the sixth field effect transistor, and the other end of the eighth resistor serves as a voltage input terminal of the first signal processing unit; one end of the first capacitor is connected to the drain of the seventh field effect transistor, and the other end of the first capacitor is grounded; a gate of the eighth field effect transistor is connected to a gate of the seventh field effect transistor, a source of the eighth field effect transistor is grounded, and a source of the eighth field effect transistor is connected to the drain of the seventh field effect transistor, a gate of the ninth field effect transistor, and a gate of the tenth field effect transistor; a source of the ninth field effect transistor is grounded, and a drain of the ninth field effect transistor is connected to a drain of the tenth field effect transistor; and a source of the tenth field effect transistor is connected to a supply voltage.

15. The circuit board according to claim 10, wherein the resistance of the second resistor is N times the resistance of the first resistor, and wherein N is the number of the plurality of current detection terminals.

16. The circuit board according to claim 13, wherein the resistance of the sixth resistor is X times the resistance of the fifth resistor, and wherein X is the number of the plurality of power stage chips in the corresponding current module.

17. An electronic device, comprising a circuit board comprising a parallel circuit architecture for a plurality of multi-phase power stage chips which comprises:
a master controller module, comprising a plurality of current detection terminals and a plurality of pulse output terminals, wherein the number of the plurality of current detection terminals is one-to-one correspondence with the number of the plurality of pulse output terminals; and
a plurality of current modules one-to-one corresponding to the plurality of current detection terminals, wherein each of the plurality of current modules comprises a plurality of power stage chips, the number of the plurality of pulse output terminals is equal to the number of the plurality of power stage chips in one of the plurality of current modules, and a control terminal of each of the plurality of power stage chips in each of the plurality of current modules is connected to one of the plurality of pulse output terminal in one-to-one correspondence,
wherein the plurality of current detection terminals are each connected to a current detection pin of one of the plurality of power stage chips in a corresponding current module, and the plurality of power stage chips in the respective current modules, which are connected to plurality of the current detection terminals, are connected to different pulse output terminals; and
the master controller module is configured to:
output a pulse signal through the respective pulse output terminals, and detect currents of corresponding power stage chips through the plurality of current detection terminals connected to the master controller module;
in response to detecting that the current at a target current detection terminal is greater than the current at the remaining current detection terminals, reduce a duty cycle of a pulse signal at a pulse output terminal connected to a power stage chip connected to the target current detection terminal; and
in response to detecting that the current at the target current detection terminal is less than the current at the remaining current detection terminals, increase the duty cycle of the pulse signal at the pulse output terminal connected to the power stage chip connected to the target current detection terminal.

18. The electronic device according to claim 17, wherein the master controller module comprises a plurality of first signal processing subcircuits that are in one-to-one correspondence with the plurality of pulse output terminals, wherein
the first signal processing subcircuit comprises a first operational transconductance amplifier, a first resistor, a second resistor, a third resistor, a first current source, and a first signal processing unit, wherein a positive input terminal of the first operational transconductance amplifier is grounded through the first resistor, both the positive input terminal of the first operational transconductance amplifier and the first resistor serve as a first current input terminal of the first signal processing subcircuit, and the first current input terminal is connected to a corresponding current detection terminal; an inverting input terminal of the first operational transconductance amplifier is grounded through the second resistor, both the inverting input terminal of the first operational transconductance amplifier and the second resistor serve as a second current input terminal of the first signal processing subcircuit, and the second current input terminal is connected to the target current detection terminal; an output terminal of the first operational transconductance amplifier is grounded through the third resistor; an output terminal of the first current source and a voltage input terminal of the first signal processing unit are connected to a net between the third resistor and the output terminal of the first operational transconductance amplifier; and an output terminal of the first signal processing unit serves as the pulse output terminal corresponding to the target current detection terminal, and a signal input terminal of the first signal processing unit is connected to a signal output terminal of the first signal processing unit; and
the first signal processing unit is configured to increase or reduce the duty cycle of an output signal at the signal output terminal of the first signal processing unit based on a voltage across the third resistance.

19. The electronic device according to claim 18, wherein the first signal processing unit comprises a first field effect transistor, a second field effect transistor, a third field effect transistor, a fourth field effect transistor, a fifth field effect transistor, and a fourth resistor, wherein a gate of the first field effect transistor P1 serves as the signal input terminal of the first signal processing unit, the gate of the first field effect transistor is connected to a gate of the second field effect transistor N1, a drain of the first field effect transistor is connected to a drain of the second field effect transistor, and a source of the second field effect transistor is grounded; one end of the fourth resistor is connected to a source of the first field effect transistor, and the other end of the fourth resistor serves as a voltage input terminal of the first signal processing unit; one end of the first capacitor is connected to the drain of the second field effect transistor, and the other end of the first capacitor is grounded; a gate of the third field effect transistor N2 is connected to the gate of the second field effect transistor, a source of the third field effect transistor is grounded, and the source of the third field effect transistor is connected to the drain of the second field effect transistor, a gate of the fourth field effect transistor N3, and a gate of the fifth field effect transistor P2; a source of the fourth field effect transistor is grounded, and a drain of the fourth field effect transistor is connected to a drain of the fifth field effect transistor; and a source of the fifth field effect transistor is connected to a supply voltage.

20. The electronic device according to claim 19, wherein the first signal processing unit further comprises a first selector; a first input terminal of the first selector is connected to the drain of the fourth field effect transistor; and a second input terminal of the first selector is connected to the gate of the first field effect transistor; the first selector is configured to receive an external control signal, and an output terminal of the first selector serves as the signal output terminal of the first signal processing unit,
wherein in response to the external control signal being at a low level, the signal at the output terminal of the first selector is the signal at the first input terminal; and
in response to the external control signal being at a high level, the signal at the output terminal of the first selector is the signal at the second input terminal.
